(19) United States
(12) Patent Application Publication
(10) Pub. No.: US 2011/0186108 A1
(43) Pub. Date: Aug. 4, 2011

(54) Ring architecture for high efficiency solar cells

(75) Inventors: Wen Liu, Wuhan (CN); Jing Shao, Wuhan (CN); Lei Wang, Wuhan (CN); Yiwen Gong, Wuhan (CN); Jingjuan Li, Wuhan (CN); Zhimou Xu, Wuhan (CN); Yanli Zhao, Wuhan (CN); Yi Wang, Wuhan (CN); Shuang Bao Wang, Wuhan (CN); Jing Nie, Wuhan (CN)

(73) Assignee: HUAZHONG UNIVERSITY OF SCIENCE AND TECHNOLOGY

(21) Appl. No.: 13/064,771

(22) Filed: Apr. 14, 2011

Related U.S. Application Data
(63) Continuation-in-part of application No. PCT/CN2011/070372, filed on Jan. 18, 2011.

(30) Foreign Application Priority Data
Jan. 19, 2010 (CN) 201010031383.0
Sep. 19, 2010 (CN) 201010286660.2
Sep. 19, 2010 (CN) 201010286749.9

(51) Int. Cl. H01L 31/052

(52) U.S. Cl. 136/246

(57) ABSTRACT

A high efficiency multiring solar cell (MRSC) system, including a number of single-junction solar cells and utilizing a novel multiring architecture is disclosed. Sunlight from the solar concentrator illuminates a double cone prism to create spatially separated spectral bands. Projection of the spectral bands on working surfaces of solar cells creates a sequence of spatially separated spectral rings, where rings corresponding to the spectral bands with longer wavelengths are enclosed by the rings corresponding to shorter wavelengths. The number of solar cells and their shape corresponds to the number and the shape of the respective spectral rings. Each solar cell is optimized for efficiently converting the sunlight from the corresponding spectral band. A corresponding method of forming solar cells and converting sunlight into electricity are also provided.

### CROSS REFERENCE TO RELATED APPLICATIONS

The present application is a Continuation-in-Part from PCT application serial number PCT/CN2011/070372 filed on Jan. 18, 2011, which claims benefit of Chinese patent applications serial number 201010031383.0 filed on Jan. 19, 2010, serial number 201010286749.9 filed on Sep. 19, 2010, and serial number 201010286660.2 filed on Sep. 19, 2010, the entire contents of which are incorporated herein by reference.

### FIELD OF THE INVENTION

The present invention is related to the field of photovoltaics and solar cells, and in particular to a ring architecture of solar cells for efficient conversion of sunlight into electricity.

### BACKGROUND OF THE INVENTION

To improve the efficiency of converting sunlight into electricity using solar cells, prior art has taught to break the incident sunlight radiation into spatially separated spectral bands using a suitable dispersion element, for example, prism or diffraction grating, as described for example in a U.S. Pat. No. 4,021,267 to Dettling. For each spectral band, a corresponding solar cell is placed in the location occupied by the spectral band, the corresponding solar cell being optimized for the conversion of sunlight of the spectral band. As a result, the overall efficiency of the sunlight conversion has been greatly improved.

However, these improvements of the prior art have been achieved at the expense of introducing additional optical elements, such as the dispersion element, which has increased the space occupied by the sunlight conversion unit, and also increased its weight and cost. This, in turn, has made the sunlight tracking system bulkier, heavier, more expensive and less reliable. Additionally, a certain distance needs to be provided between the solar cell and optical elements to properly focus sunlight. As a result, solar cell systems have been packaged within bulky enclosures, resulting in higher material and assembly costs, and more expensive shipping.

Accordingly, there is a need in industry for further development of an improved architecture for a solar cell system, which would mitigate or avoid the above noted deficiencies of the prior art.

### SUMMARY OF THE INVENTION

There is an object of the invention to provide an improved architecture for high efficiency solar cells and corresponding methods of forming solar cells and converting sunlight into electricity.

According to one aspect of the invention, there is provided an array of solar cells, comprising:
a plurality of solar cells made of a photovoltaic material, each solar cell having a shape of a ring; each ring having a working surface receiving a corresponding spectral band of a solar radiation;
the shape of each ring being formed as a complement of inner space relative to an outer space, the inner space being enclosed by the outer space;
the plurality of the solar cells being spatially arranged to form a sequence of solar cells, wherein a succeeding solar cell is enclosed within a preceding solar cell in the sequence; and
the photovoltaic material of each solar cell being optimized for converting respective spectral band into electricity.

In the embodiments of the invention, the rings in the array of solar cells are substantially circular rings or elliptical rings.

In order to generally correlate with properties of the solar spectrum, an area of said working surface of the ring is larger for shorter wavelengths of the solar spectrum.

In embodiments of the invention, some or all solar cells further comprise a layer of photonic crystal for enhancing light trapping properties, and may optionally further comprise a layer of distributed Bragg reflector.

In the embodiments of the invention, the solar cells are single junction solar cells connected in series or in parallel.

Conveniently, the last solar cell in the sequence of solar cells, which does not have a succeeding solar cell, may be an infrared solar cell.

According to another aspect of the invention, there is provided a method of forming an array of solar cells, comprising steps of:
forming a plurality of solar cells made of a photovoltaic material, each solar cell having a shape of a ring;
forming the shape of each ring as a complement of inner space relative to an outer space, the inner space being enclosed by the outer space;
spatially arranging the plurality of the solar cells to form a sequence of solar cells, wherein a succeeding solar cell is enclosed within a preceding solar cell in the sequence; and
optimizing the photovoltaic material of each solar cell for converting a spectral band of a solar spectrum.

According to yet another aspect of the invention, there is provided a sunlight conversion unit, comprising:

(i) a dispersion element spreading incident sunlight into spectral components, a range of spectral components defining a spectral band;
(ii) an array of solar cells, comprising:
a plurality of solar cells made of a photovoltaic material, each solar cell having a shape of a ring, each ring having a working surface receiving a corresponding spectral band from the dispersion element;
the shape of each ring being formed as a complement of inner space relative to an outer space, the inner space being enclosed by the outer space;
the plurality of the solar cells being spatially arranged to form a sequence of solar cells, wherein a succeeding solar cell is enclosed within a preceding solar cell in the sequence; and
the photovoltaic material of each solar cell being optimized for converting the corresponding spectral band;
a shape of said working surface of a ring substantially corresponds to a shape of an area on the working surface illuminated by the corresponding spectral band.

In the sunlight conversion unit of the embodiments of the invention, the ring is substantially a circular ring or an elliptical ring.

In the sunlight conversion unit described above, the dispersion element is a cone prism or a double cone prism.

In one embodiment of the invention, the cone prism is a composite cone prism, comprising:
a number of optical elements in a form of polyhedra made of optically transparent material;
each polyhedron having a first triangular face, and a second triangular face, one rectangular lateral face having two lateral edges, and two trapezoidal lateral faces of equal size having a common lateral edge whose length is shorter than a length of said two lateral edges, the first triangular face being perpendicular to the lateral faces;
the trapezoidal lateral faces of all polyhedra being the same;
the first and second triangular faces being polished; and
the number of polyhedra and angles of triangular faces are chosen so that to ensure the polyhedra are assembled together so that trapezoidal lateral faces of any two neighboring polyhedra coincide, thereby forming a composite conical prism.

Conveniently, all polyhedrons are the same. In the embodiments of the invention, the cone prism is assembled of 6 to 20 identical polyhedrons.

Alternatively, the sunlight conversion unit described above may comprise a double cone prism, wherein a second prism is a mirror copy of the first cone prism relative to a plane containing the first triangular faces.

According to one more aspect of the invention, there is provided a method of converting sunlight into electricity, comprising steps of:

(i) spreading an incident sunlight into spectral components, a range of spectral components defining a spectral band;
(ii) forming an array of solar cells, comprising:
forming a plurality of solar cells made of a photovoltaic material, each solar cell having a shape of a ring, each ring having a working surface receiving a corresponding spectral band;
forming the shape of each ring as a complement of inner space relative to an outer space, the inner space being enclosed by the outer space;
spatially arranging the plurality of the solar cells to form a sequence of solar cells, wherein a succeeding solar cell is enclosed within a preceding solar cell in the sequence;
optimizing the photovoltaic material of each solar cell for converting the corresponding spectral band into electricity; and
   (iii) arranging a shape of the working surface of the ring to substantially correspond to a shape of an area on the working surface illuminated by the corresponding spectral band.

According to yet one more aspect of the invention, there is provided a solar cell system, comprising:

(i) a sunlight concentrator, collecting sunlight and converting the collected sunlight into concentrated sunlight of higher intensity;
(ii) a dispersion element receiving the concentrated sunlight and spreading the concentrated sunlight into spectral components, a range of spectral components defining a spectral band;
(iii) an array of solar cells, comprising:
a plurality of solar cells made of a photovoltaic material, each solar cell having a shape of a ring, each ring having a working surface receiving a corresponding spectral band from the dispersion element;
the shape of each ring being formed as a complement of inner space relative to an outer space, the inner space being enclosed by the outer space;
the plurality of the solar cells being spatially arranged to form a sequence of solar cells, wherein a succeeding solar cell is enclosed within a preceding solar cell in the sequence; and
the photovoltaic material of each solar cell being optimized for converting the corresponding spectral band;
wherein a shape of the working surface of the ring substantially corresponds to a shape of an area on the working surface illuminated by the corresponding spectral band.

In the solar cell system described above, the sunlight concentrator comprises one of the following:
two confocal reflectors; or
two non-confocal reflectors and adjustable refractive element transforming a non-parallel beam into a substantially parallel beam.

According to yet one more aspect of the invention, there is provided a composite cone prism, comprising:
a number of optical elements in a form of polyhedra made of optically transparent material;
each polyhedron having a first triangular face, and a second triangular face, one rectangular lateral face having two lateral edges, and two trapezoidal lateral faces of equal size having a common lateral edge whose length is shorter than a length of said two lateral edges, the first triangular face being perpendicular to the lateral faces;
the trapezoidal lateral faces of all polyhedra being the same;
the first and second triangular faces being polished; and
the number of polyhedra and angles of triangular faces are chosen so that to ensure the polyhedra are assembled together so that trapezoidal lateral faces of any two neighboring polyhedra coincide, thereby forming a composite conical prism.

Conveniently, in the composite cone prism described above, all polyhedra are the same.

In the embodiments of the invention, the composite cone prism is a double cone prism, further comprising a second cone prism, which is a mirror copy of the first cone prism relative to a plane containing the first triangular faces.

Thus, an improved array of solar cells, a sunlight conversion unit, a solar cell system, a method of forming an array of solar cells, a method of converting sunlight into electricity, and a cone prism of a new design for use in a solar cell system have been provided.

### BRIEF DESCRIPTION OF THE DRAWINGS

Embodiments of the present invention will now be described, by way of example, with reference to the accompanying drawings in which:

FIG. 1 illustrates a confocal sunlight concentrator for use in a solar cell system of the embodiments of the invention;

FIG. 2 illustrates a double cone prism of the embodiment of the present invention;

FIG. 3a illustrates a spatial distribution of a spectral component created by the double cone prism of FIG. 2 in the form of a monocolored cone surface;

FIG. 3b illustrates a spatial distribution and a shape of the projection of a spectral band created by the double cone prism of FIG. 2;

FIG. 3c illustrates a spatial distribution of the infrared spectral band created by the double cone prism of FIG. 2;

FIG. 4 illustrates a general tendency of the solar spectrum;

FIG. 5 illustrates a geometrical shape of a solar cell of the embodiments of the invention;

FIG. 6 illustrates structure of a single-junction solar cell of the embodiment of the present invention;

FIG. 7 shows an array of solar cells of the embodiment of the invention;

FIG. 8 illustrates s solar cell system of the embodiments of the invention including the array of solar cells of FIG. 7;

FIG. 9 illustrates the solar cell system of the embodiments of the invention including a modified solar concentrator;

FIG. 10a illustrates a triangular prism used for creating a polyhedron optical component for the composite dispersion element of the embodiment of the present invention;

FIG. 10b illustrates pieces of the triangular prism of FIG. 7a to be removed for forming the polyhedron optical component of the composite dispersion element of the embodiment the present invention;

FIG. 10c illustrates the resulting polyhedron optical component of the composite dispersion element of the embodiments of the present invention;

FIG. 11a illustrates two neighboring polyhedra optical components to be assembled together;

FIG. 11b shows a top view of the assembled composite dispersion element of the embodiment of the present invention;

FIG. 12a illustrates a triangular prism used for creating a modified polyhedron optical component for an alternative composite dispersion element of the embodiment of the invention; and

FIG. 12b illustrates a resulting polyhedron optical component of the alternative composite dispersion element of the embodiment of the invention.

### DESCRIPTION OF THE EMBODIMENTS OF THE INVENTION

To overcome the shortcomings of prior art solutions, while retaining existing advantages of the prior art, the embodiments of the present invention introduce a sequence of solar cells having a ring architecture as will be described in detail below.

The embodiments of the invention provide an array of solar cells made of photovoltaic materials and having a shape of three dimensional rings of circular, elliptical, or generally arbitrary form. The shape of each ring is defined as a complement of an inner space relative to an outer space, the inner space being enclosed by the outer space. The solar cells are spatially arranged to form a sequence of solar cells so that a succeeding solar cell is enclosed within a preceding solar cell in the sequence. The solar cells of the embodiments of the invention comprises a sequence of rings, where each larger outer ring encloses a smaller inner ring, the last solar cell having a shape of a disk, which does not enclose any further solar cell.

Each ring in the sequence of rings has a surface, receiving a corresponding spectral band of a solar radiation produced by a dispersion element. The photovoltaic material of each solar cell is optimized for converting respective spectral band into electricity.

A corresponding sunlight conversion unit, and a solar cell system, comprising the ring array of solar cells are also provided. A method of forming the ring array of solar cells, and a method of converting sunlight into electricity using the ring array of solar cells are further described in the patent application.

The embodiments of the present invention also describe an improved dispersion element that breaks an incident sunlight radiation into spatially separated spectral bands, each spectral band corresponding to a respective shape of the solar cell, and projects each spectral band on a receiving surface of the corresponding solar cell. The dispersion element of the embodiments of the invention is a cone prism, and preferably a composite double cone prism, which is assembled from a number of identical polyhedra elements for costs savings.

### First Embodiment of the Invention

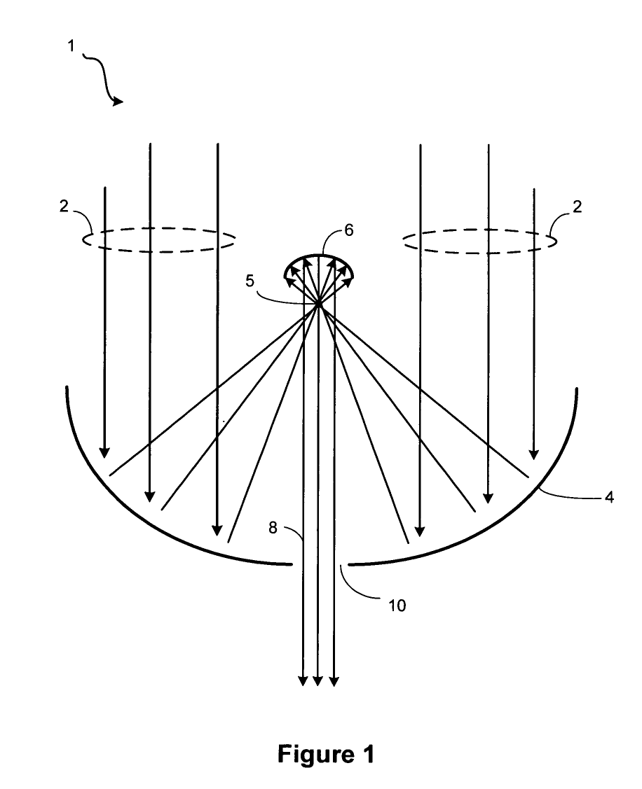

The first embodiment of the invention will be described in detail with reference to FIGS. 1-8.

FIG. 1 illustrates the sunlight concentrator 1 used in a solar cell system of the embodiment of the invention, the sunlight concentrator 1 collecting the sunlight and converting the collected sunlight into concentrated sunlight of higher intensity.

An incident sunlight 2 shines on a parabolic mirror 4 having diameter of about 1 meter, a length of about 0.18 m, a focal length of about 0.45 m. The mirror 4 is made of 5 mm thick aluminum coated with a vacuum metalized polyester film (not shown) as a reflective surface. The mirror 4 reflects the incident sunlight 2 on a smaller parabolic mirror 6 having diameter of about 0.02 m, length of about 0.02 m, and a focal length of about 0.002 m. The smaller mirror 6 is made of 3 mm thick aluminum coated with the vacuum metalized polyester film (not shown) to provide a good reflection of sunlight. Both mirrors 4 and 6 are confocal, i.e. they are aligned in such a way that their foci coincide in a point designated by the reference numeral 5. The mirror 6 is designed to concentrate the sunlight collected by the mirror 4 into a narrow beam 8, whose diameter is comparable with a typical size of solar cells used for converting the sunlight into electricity (up to several centimeters). The size of the beam 8 depends on the ratio of the foci of the mirrors 4 and 6, the typical ratio being about ˜200. To minimize a negative impact of shadowing of the mirror 4 by the mirror 6, the diameter of the mirror 6 is kept as low as possible, typical ratio of the diameter of the mirror 4 to the diameter of the mirror 6 being about ˜50. The mirror 4 has an opening 10 to let the beam 8 out for further processing. The size of the opening 10 is commensurate with the size of the beam 8.

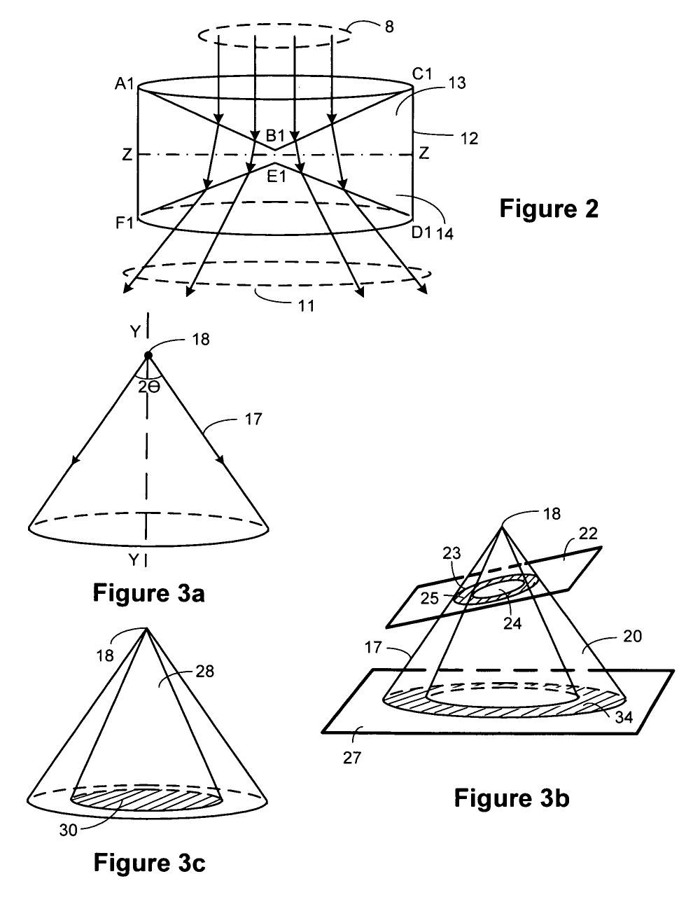

The beam 8 is further processed by the dispersion element 12, which is a double cone prism 12 shown on FIG. 2. The double cone prism 12 (A1-B1-C1-D1-E1-F1) has two cone prisms, a first cone prism 13, and another, second cone prism 14, which is a mirror copy of the first cone prism 13 relative to a symmetry plane Z-Z. The first and second cone prisms 13 and 14 are made of high quality K9 quartz glass, characterized by high refractive index of about 1.4585, a broad transparency wavelength range from 185 micrometers to 3500 micrometers (depending on the grade of the glass), and capable of withstanding high temperatures, the softening point being up to 1730° C. The double cone prism 12 spreads the beam 8 into spectral components 11, each spectral component 11 forming a monocolored conical surface (MCS) 17 as shown in FIG. 3a. All MCSs have the same imaginary apex 18 and different aperture 2θ, depending on the wavelength (color) of each spectral component, where wider aperture 2θcorresponds to a shorter wavelength. Spectral components 11 of a selected spectral range define a spectral range. For example, spectral components 11 defined by MCS 17 and MCS 19, form a spectral band 20 as shown in FIG. 3b.

When intersecting with an inclined plane 22, each MCS forms an ellipse, for example, ellipse 23 formed by the MCS 17, or ellipse 24 formed by the MCS 19. Thus, the ellipses 23 and 24 define an elliptical spectral ring 25 corresponding to the spectral band 20. Each spectral band, other than the infrared spectral band, forms a corresponding elliptical spectral ring when intersected with the plane 22.

When intersecting with a plane 27 normal to an axis of symmetry Y-Y of an MCS shown in FIG. 3a, the spectral band 20 forms a circular ring 34 as shown in FIG. 3b.

MCSs belonging to the infrared spectral band 28 form a spectral disk 30 as shown in FIG. 3c.

Since spectral rings formed by spectral components of shorter wavelength enclose spectral rings formed by spectral components of longer wavelength, the former spectral rings cover a larger area then the latter.

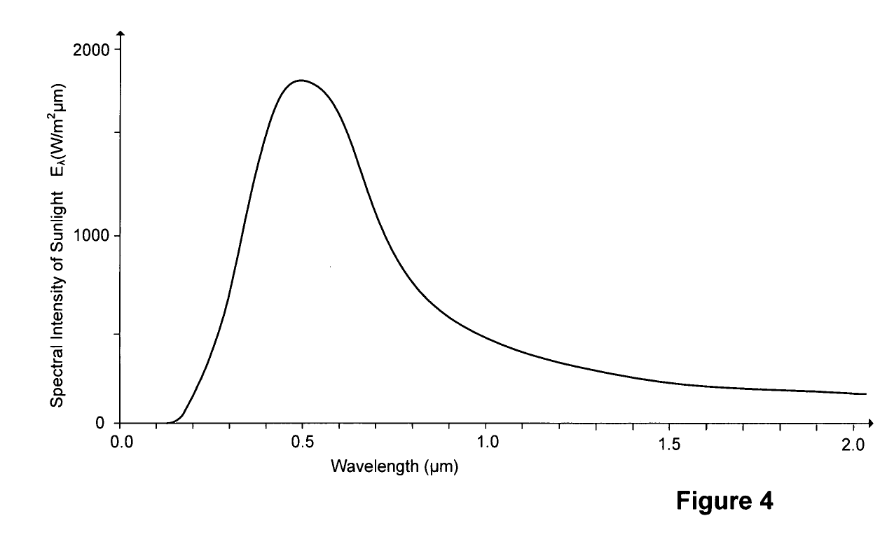

This property of the enclosed spectral ring geometry favorably correlates with a general tendency of spectral components of sunlight to increase in intensity from the infrared part of the solar spectrum up to the peak of the solar spectrum at the wavelength of approximately 0.5 micrometers as illustrated in FIG. 4.

This general tendency allows for a more uniform distribution of intensity of sunlight across the spectral rings than in the linear geometry of the prior art, which is beneficial for optimizing the efficiency and the cost of solar cells.

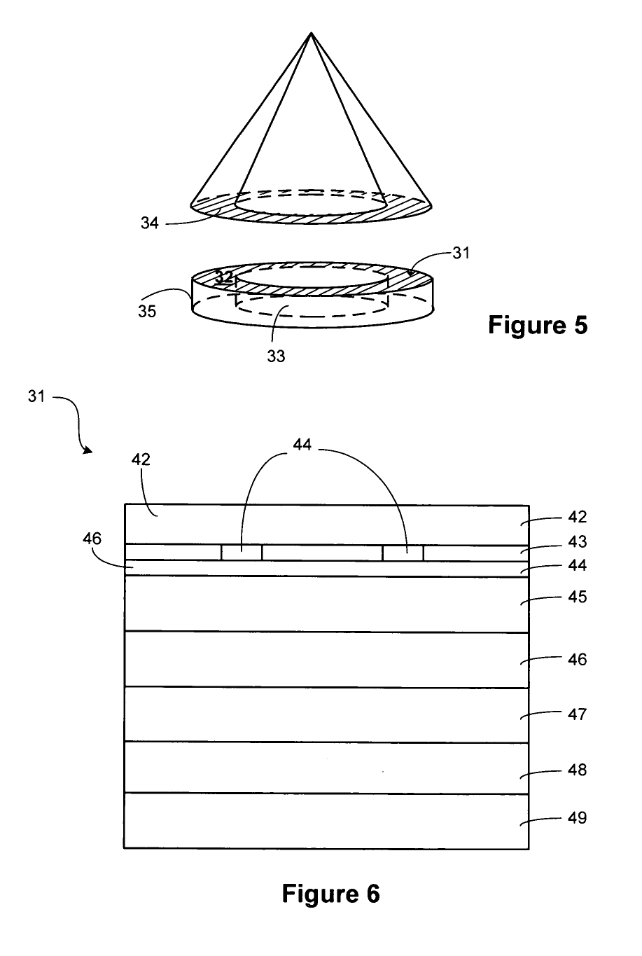

The sunlight from each spectral band is converted into electricity by placing a solar cell 31, shaped in the form of a corresponding spectral ring, into the area occupied by the corresponding spectral ring. For example, a solar cell 31 has the same shape of a working surface 32 as the spectral ring 34. The solar cell 31 is placed into the area occupied by said spectral ring so that the working surface 32 substantially overlaps with the spectral ring 34 as shown in FIG. 5. For clarity, the solar cell 31 and the spectral ring 34 are shown slightly spaced apart, whereas in reality, the spectral ring 34 and the working surface 32 overlap.

A ring shape of the solar cell 31 is best explained as a complement of an inner space, in a form of a cylinder 33, relative to an outer space, in a form of a cylinder 35, the inner space 33 being enclosed by the outer space 35. In other words, the complement of the inner space 33 relative to the outer space 35 resembles a shape of a wedding ring, which is the shape of the solar cell 31.

The solar cell 31 of a ring shape is made from a wafer by using a modern laser cutting technology or, alternatively, by an epitaxial deposition using suitable shadow masks.

Each solar cell is a single junction solar cell made from a photovoltaic material designed to efficiently convert sunlight from the corresponding spectral band by adjusting the energy band gap of the solar cell to correspond to the minimal energy of photons associated with the spectral components forming the spectral band.

The structure of the solar cell 31 is schematically shown in FIG. 6. The solar cell 31 is composed of several layers made of different materials, each layer serving a specific purpose as explained below. The first layer is a transparent protective layer 42, which seals the solar cell 31 from the environmental damage. Beneath the protective layer 42, there is a contact grid, or electrodes 43, made of a good conductor of electricity and designed to collect electrons. Since the contact grid 43 is opaque, it should be spaced widely enough to let most of the sunlight enter the solar cell 31, while still being able to collect the current produced by the solar cell 31. An anti-reflection layer 44 is placed next, which substantially eliminates reflection of sunlight by the solar cell 31.

N-type silicon layer 45 is placed below the anti-reflection layer 44, and made of the pure silicon (Si) doped with compounds, such as Phosphorus or Arsenic, to create majority carriers, valence electrons, available for conduction. P-type silicon layer 46 is placed below the N-type silicon layer 45, and created by doping pure Si with compounds, such as Boron, to create minority carriers, or holes, available for conduction. The area of contact between the N-silicon layer 45 and the P-silicon layer 46 creates a p-n junction, which allows movement of free electrons, if any, only in one direction. When the solar cell 31 is illuminated by sunlight, which can be thought of as a stream of photons, the energy of the photons is absorbed by some of the electrons in atoms. This additional energy allows the electrons to escape from their normal positions in atoms and to become free electrons available for conduction. To enhance sunlight trapping capabilities of the solar cell 31, an additional photonic crystal layer 47, made of a porous silicon, is placed below the P-silicon layer 46. The photonic crystal layer 47 diffracts the sunlight so that it reenters the P-silicon layer 46 at a lower angle and therefore travels longer distances in the solar cell 31, which increases the probability of the sunlight to be absorbed and generate free electrons. An additional distributed Bragg reflection (DBR) layer 48 helps to prevent losses of light through the bottom of the solar cell. The last layer is a back electrical conductor, or electrode 49, which covers an entire back surface of the solar cell 31.

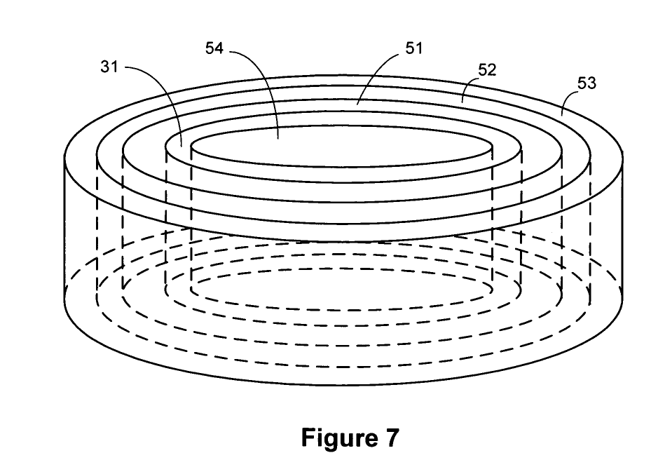

Since the dispersion element 12 spreads the sunlight into a number of spectral bands, a corresponding plurality of the ring shaped solar cells is formed, defining an array of solar cells 50 illustrated in FIG. 7. The plurality of the solar cells in the array of solar cells 50 are spatially arranged to form a sequence of solar cells, wherein a succeeding solar cell is enclosed within a preceding solar cell in the sequence. For example, the solar cell 31 is enclosed within the solar cell 51, and the solar cell 52 is enclosed within the solar cell 53.

The last solar cell 54 in the sequence has a shape of a disk and does not have a succeeding solar cell. The shape of the last solar cell 54 is determined by the shape of the infrared spectral band 28 forming the spectral disk 30 of FIG. 3c.

The photovoltaic material of each solar cell is optimized for converting a respective spectral band into electricity.

Solar cells of the array of solar cells 50 are electrically connected, which converts sunlight into electricity more efficiently than a single conventional solar cell of equal size. If it is desired to increase the output current, the solar cells in the array of solar cells 50 are connected in parallel. Otherwise, the solar cells in the array of solar cells 50 are connected in series to increase the output voltage.

A method of forming an array of solar cells described above is also provided. The method comprises forming a plurality of solar cells made of a photovoltaic material, each solar cell having a shape of a ring; forming the shape of each ring as a complement of inner space relative to an outer space, the inner space being enclosed by the outer space; spatially arranging the plurality of the solar cells to form a sequence of solar cells, wherein a succeeding solar cell is enclosed within a preceding solar cell in the sequence; and optimizing the photovoltaic material of each solar cell for effectively converting a spectral band of a solar spectrum.

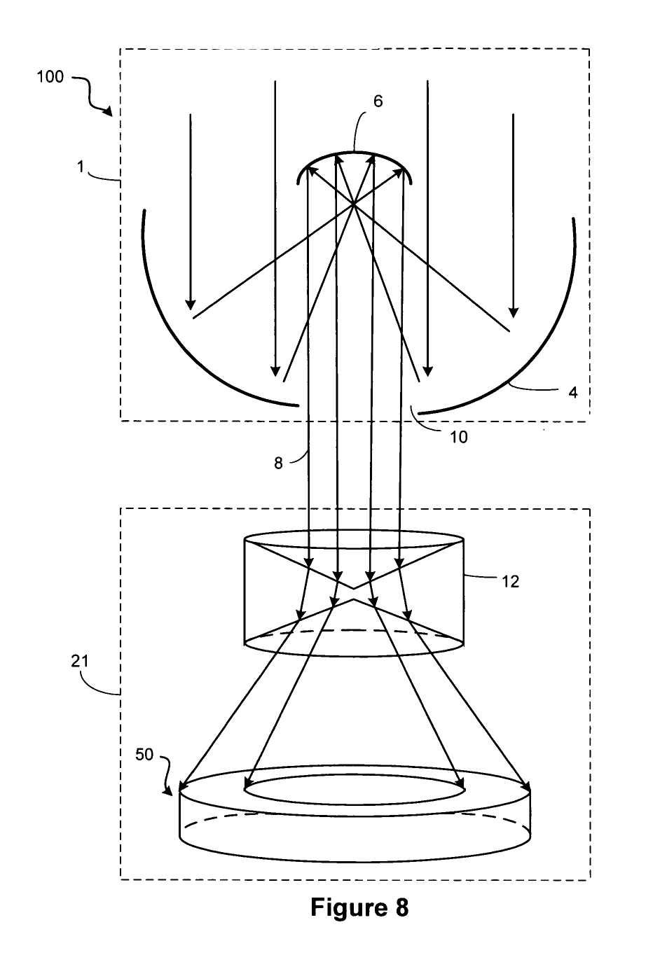

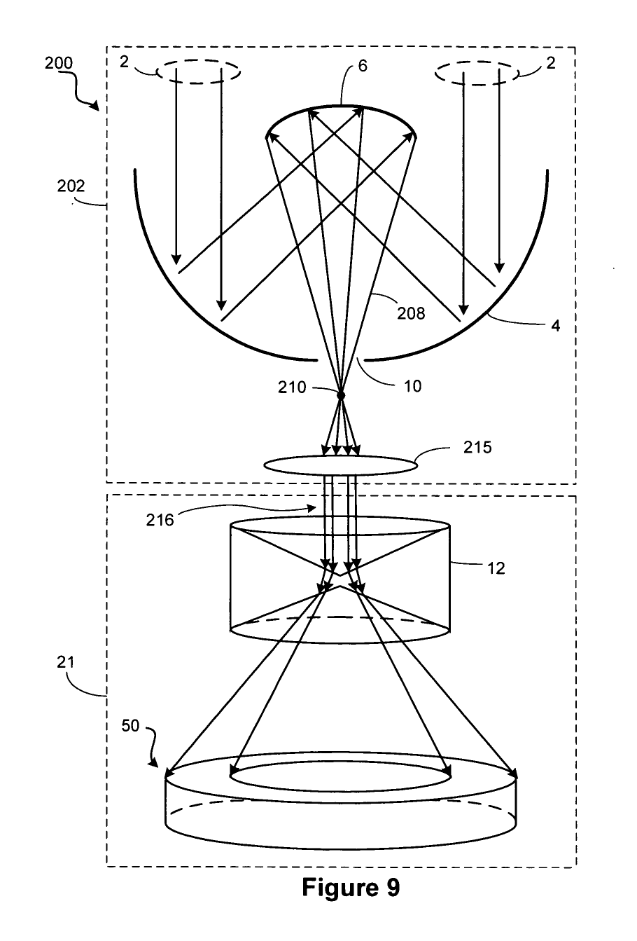

The dispersion element 12 of FIG. 2 and the array of solar cells 50 of FIG. 7 form a sunlight conversion unit 21, shown in FIGS. 8 and 9, which converts light into electricity.

A corresponding method of converting sunlight into electricity is also provided. The method performs the following steps: (i) spreading incident sunlight into spectral components, a range of spectral components defining a spectral band; (ii) forming an array of solar cells, comprising: forming a plurality of solar cells made of a photovoltaic material, each solar cell having a shape of a ring, each ring having a working surface receiving a corresponding spectral band; forming the shape of each ring as a complement of inner space relative to an outer space, the inner space being enclosed by the outer space; spatially arranging the plurality of the solar cells to form a sequence of solar cells, wherein a succeeding solar cell is enclosed within a preceding solar cell in the sequence; optimizing the photovoltaic material of each solar cell for converting the corresponding spectral band into electricity; and (iii) arranging a shape of the working surface of the ring to substantially correspond to a shape of an area on the working surface illuminated by the corresponding spectral band.

A solar cell system 100 of the embodiment of the invention is shown in FIG. 8. It comprises the sunlight concentrator of FIG. 1, and a sunlight conversion unit 21 including the dispersion element 12 of FIG. 2, and the array of solar cells 50 of FIG. 7 described above.

Thus, an improved array of solar cells 50, the sunlight conversion unit 21, the solar cell system 100, the method of forming the array of solar cells 50, and the method of converting sunlight into electricity have been provided.

### Second Embodiment of the Invention

FIG. 9 illustrates another embodiment of the solar cell system 200, including a modified solar concentrator 202.

Given the difficulties in keeping the confocal alignment of the mirrors 4 and 6, for example, because of the varying whether conditions, in the modified solar concentrator 202, the foci of the mirrors 4 and 6 are misaligned to produce a slightly convergent beam 208 with the focal point 210 slightly below the opening 10 in the mirror 4. An additional optical element, an optical lens 215, is added to convert the beam 208 into a parallel beam 216. This provides the benefit of easier maintenance of the solar concentrator 202 by adjusting the position of the optical lens 215 instead of adjusting the position of the mirror 6, which is much more difficult to accomplish. The optical lens 215 is made from the same K9 quartz glass as the dispersion element 12, since both optical elements process the concentrated sunlight of high intensity (200-500 suns). Alternatively, other optical materials, such as K10 or BK7 can be used, and the lens 215 can be a short-focused Fresnel lens.

The solar system 200 further comprises the sunlight conversion unit 21, comprising the dispersion element 12 and the array of solar cells 50 as described above.

### Third Embodiment of the Invention

Although the dispersion element 12, being a double cone prism, has excellent mechanical and optical properties, it has a shortcoming of being complex and expensive in manufacturing.

To mitigate this shortcoming, the third embodiment of the invention teaches an alternative design of the dispersion element 12.

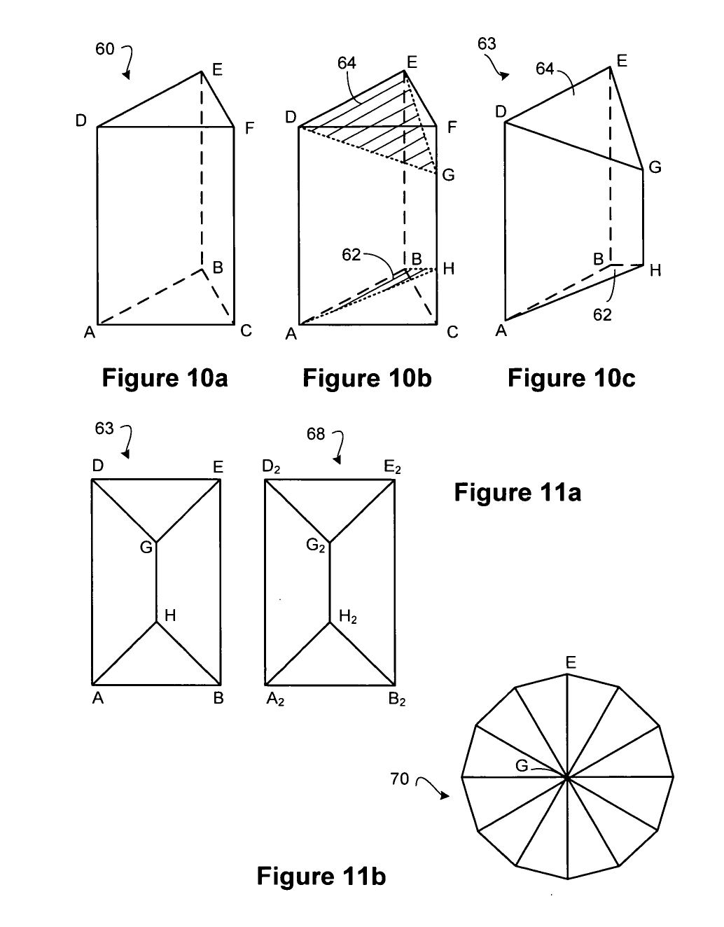

In the alternative design, the double cone prism 12 is not monolithic anymore, but is assembled from a number of optical elements, for example, 12 elements, each optical element being relatively cheap and easy to manufacture. Each optical element has a form of polyhedron 63 of FIG. 10c, and is made out of a right triangular glass prism 60 with vertices ABCDEF of FIG. 10a. The angle between lateral faces ADFC and FEBC of the triangular prism 60 is equal to 30°, i.e. ∠ACB=30° (FIG. 10a). The bottom part of the right prism 60 is cut along the plane ABH (see FIG. 10b), thereby forming a first triangular face 62 of the polyhedron 63 of FIG. 10c with vertices AHB. The top part of the right prism 60 is cut along the plane DGE (FIG. 10b), thereby forming a second triangular face 64 of the polyhedron 63 of FIG. 10c with vertices DEG. As a result, the polyhedron 63 is formed with vertices ABHDEG, as shown in FIG. 10c. The polyhedron 63 has one rectangular lateral face ADEB having two lateral edges AD and EB, and two trapezoidal lateral faces of equal size ADGH and BEGH having a common lateral edge GH whose length is shorter than the length of said two lateral edges AD and EB.

First and second triangular faces DEG and ABH of the polyhedron 63 are polished. Polishing is not required for all other lateral faces, which reduces manufacturing costs.

In a similar manner, the total of twelve polyhedra identical to the polyhedron 63 are made.

Two such identical polyhedra 63 and 68 with vertices ABHDEG and A₂B₂H₂D₂E₂G₂, correspondingly, are shown side by side on FIG. 11a. Polyhedra 63 and 68 are assembled together by placing the face HGEB against the face H₂G₂D₂A₂ and gluing them together with a high quality UV transparent glue. The remaining 10 polyhedra are added to an assembly of the polyhedra 63 and 68 in the same manner as described above, so that trapezoidal lateral faces of any two neighboring polyhedra coincide, thereby forming a double cone composite prism 12 whose top view 70 is illustrated in FIG. 11b. For clarity, the top edges of the constituent polyhedra, are shown without naming their vertices except for the edge GE of polyhedron 63. However, in reality, the edges would be hardly visible, since the refractive index of the UV transparent glue closely matches the refractive index of the glass.

A fully assembled twelve polyhedra closely resemble a monolithic double cone dispersion element 12 of FIG. 2 and operate in a similar manner. The double cone composite prism 12 whose top view 70 is shown in FIG. 11b spreads the sunlight beam 8 into spectral components, each spectral component forming a surface, which closely resembles MCSs described above, for example, the MCSs 17 and 19 of FIG. 3b of the first embodiment of the present invention.

Correspondingly, spectral rings of the third embodiment of the present invention will slightly differ, but still closely resemble circular or elliptical spectral rings of the first embodiment of the present invention, which may require the adjustment of the geometrical shape of the solar cells 31 of the array of solar cells 50 correspondingly, but the solar cells 31 will continue to operate as intended without departure from the spirit and scope of the embodiments of the present invention.

The number of polyhedra in the composite double cone prism 12, whose top view 70 is shown in FIG. 11b, may be greater or smaller than twelve. For example, the number of polyhedra may be 6, 8 or 20, or any other required number. The general tendency is that an increased number of polyhedra in the composite double cone prism gives rise to a higher degree of similarity between the shape of the spectral rings produced by the monolithic double cone dispersion element 12 and the composite double cone prism 12 whose top view 70 is shown in FIG. 11b.

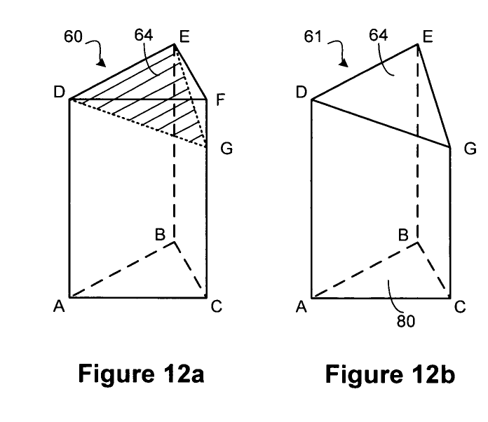

In yet alternative embodiment, the dispersion element 12 is designed as a single cone composite prism assembled from a number of polyhedra prepared as shown in FIGS. 12a and 12b. Namely, the right triangular prism 60 is now only cut at the top along the plane DGE (FIG. 12a), whereas the bottom part of the right prism remains unchanged, resulting in polyhedron 61 ABCDEG of FIG. 12b. The single cone composite prism is assembled of polyhedra 61 in the same manner as the double cone composite prism described above.

Thus, a composite cone prism of the alternative design is made of a number of optical elements in the form of polyhedra 61 made of optically transparent material;
each polyhedron having a first triangular face 80, and a second triangular face 64, one rectangular lateral face ABED having two lateral edges AD and BE, and two trapezoidal lateral faces of equal size ADGC and BEGC having a common lateral edge GC whose length is shorter than a length of said two lateral edges AD and BE, the first triangular face 80 being perpendicular to the lateral faces ADGC and BEGC;
the trapezoidal lateral faces of all polyhedra being the same;
the first 80 and second 64 triangular faces being polished; and
the number of polyhedra and angles of triangular faces are chosen so that to ensure the polyhedra are assembled together so that trapezoidal lateral faces of any two neighboring polyhedra coincide, thereby forming a composite conical prism.

In the embodiment of the invention, all polyhedra are the same. To make a double cone prism, the composite cone prism further includes another, second prism, which is a mirror copy of said cone prism relative to a plane containing the first triangular faces.

Thus, improved composite cone and double cone prisms have been provided.

The present invention has numerous advantages over prior art.

For example, the single-junction solar cells of the present invention can be illuminated by as narrow spectral bands as may be practical. The narrow spectral bands allow to fine tune the performance of the photonic crystal and DBR layers of each solar cell, which results in a higher efficiency of sunlight conversion than in the case of wider spectral bands, such as those used for sunlight conversion by the multi junction cells of the prior art.

Another advantage of the single-junction solar cells of the present invention over the multi-junction cells of the prior art is more effective use of sunlight due to the absence of the interface layers that cause unproductive loss of sunlight in multi-junction cells.

Yet another advantage of the single junction solar cells of the present invention over the multi-junction cells of the prior art is simpler design, wider choice of available photovoltaic materials and lower manufacturing costs.

The multiring architecture of the solar cells of the present invention offers the possibility of selecting a photovoltaic material for each spectral band, which is best suited for the conversion into electricity for the spectral band. For example, gallium arsenide (GaAs) photovoltaic material can be used for the visible part of the solar spectrum, and gallium antimonide (GaSb) photovoltaic material can be used for the infrared part of the solar spectrum. This results in the increased conversion efficiency of solar cells over the known prior art.

Additionally, the multiring architecture of the solar cells of the present invention allows the placement of the dispersion element about two times closer to the surface of the solar cells, which reduces space occupied by the sunlight conversion unit. More compact sunlight conversion unit allows the use of simpler, cheaper and more reliable tracking system, and helps to reduce assembly, shipping and material costs.

Various modification can be made to the embodiments of the invention.

FIG. 2 has illustrated the dispersion element in the form of the double cone prism 12. It is contemplated that the first cone prism 13, or the second cone prism 14 can be used separately instead of the double cone prism 12.

To reduce the cost, the last solar cell 54 in the array of solar cells 50 may be omitted. This central disk space can be used only for letting the infrared spectral band passing through, instead of converting the infrared spectral band into electricity.

Although the composite cone or double cone prism of the third embodiment of the invention are composed of identical polyhedra 61 or 63 correspondingly, it is understood that polyhedra having different angles between trapezoidal faces can be used, as long as the sum of said angles adds to 360 degrees form the composite cone or double cone prisms without gaps between polyhedra.

Although different polyhedra have been glued together, it is also understood that polyhedra can be brought in tight contact with each other without glue, for example, with external fixing means forming a closed loop around the composite prism.

It is also understood that different optical materials can be used for the cone or double cone composite prisms such as K9, quartz glass or flint glass.

Although solar cells of the embodiments of the invention are made of silicon, it is contemplated that other suitable materials such as cadmium telluride, copper indium gallium selenide, or other materials known in the industry, can be also used for solar cells.

Although the photonic crystal of the embodiment of the invention is made of porous silicon, it is understood that other types of photonic crystals can also be used.

Although the embodiments of the invention have described the array of solar cells forming circular or elliptical rings, it is understood that other configurations of rings, or structures closely resembling rings can be formed.

It is also understood that solar cell rings may have gaps between the rings, for example, the ring may be only a part of the complement of the succeeding space relative to the preceding space.

Yet alternatively, it is understood that solar cell rings may be interrupted by radial gaps, or modified otherwise.

This invention has been described as a number of embodiments. However, the description is not intended to limit the invention to the embodiments and applications disclosed herein. Many other modifications can be made by those skilled in the art without departure from the spirit and scope of the present invention. It is intended that the appended claims be construed to include alternative embodiments.

What is claimed is:

1. An array of solar cells, comprising:
a plurality of solar cells made of a photovoltaic material, each solar cell having a shape of a ring, each ring having a working surface receiving a corresponding spectral band of a solar radiation;
the shape of each ring being formed as a complement of inner space relative to an outer space, the inner space being enclosed by the outer space;
the plurality of the solar cells being spatially arranged to form a sequence of solar cells, wherein a succeeding solar cell is enclosed within a preceding solar cell in the sequence; and
the photovoltaic material of each solar cell being optimized for converting respective spectral band into electricity.

2. The array of solar cells of claim 1, wherein the ring is substantially a circular ring or an elliptical ring.

3. The array of solar cells of claim 1, wherein an area of said working surface of the ring is larger for shorter wavelengths of the solar spectrum.

4. The array of solar cells of claim 1, wherein some or all solar cells further comprise a layer of photonic crystal for enhancing light trapping properties.

5. The array of solar cells of claim 4, wherein said some or all solar cells further comprise a layer of distributed Bragg reflector.

6. The array of solar cells of claim 1, wherein the solar cells are single junction solar cells connected in series or in parallel.

7. The array of solar cells of claim 1, wherein the last solar cell in the sequence, which does not have a succeeding solar cell, is an infrared solar cell.

8. A sunlight conversion unit, comprising:
(i) a dispersion element spreading an incident sunlight into spectral components, a range of spectral components defining a spectral band;
(ii) an array of solar cells, comprising:
a plurality of solar cells made of a photovoltaic material, each solar cell having a shape of a ring, each ring having a working surface receiving a corresponding spectral band from the dispersion element;
the shape of each ring being formed as a complement of inner space relative to an outer space, the inner space being enclosed by the outer space;
the plurality of the solar cells being spatially arranged to form a sequence of solar cells, wherein a succeeding solar cell is enclosed within a preceding solar cell in the sequence;
the photovoltaic material of each solar cell being optimized for converting the corresponding spectral band; and
a shape of said working surface of a ring substantially corresponds to a shape of an area on the working surface illuminated by the corresponding spectral band.

9. The sunlight conversion unit of claim 8, wherein the ring is substantially a circular ring or an elliptical ring.

10. The sunlight conversion unit of claim 8, wherein the dispersion element is a cone prism or a double cone prism.

11. The sunlight conversion unit of claim 10, wherein the cone prism is a composite cone prism, comprising:
a number of optical elements in a form of polyhedra made of optically transparent material;
each polyhedron having a first triangular face, and a second triangular face, one rectangular lateral face having two lateral edges, and two trapezoidal lateral faces of equal size having a common lateral edge whose length is shorter than a length of said two lateral edges, the first triangular face being perpendicular to the lateral faces;
the trapezoidal lateral faces of all polyhedra being the same;
the first and second triangular faces being polished; and
the number of polyhedra and angles of triangular faces are chosen so that to ensure the polyhedra are assembled together so that trapezoidal lateral faces of any two neighboring polyhedra coincide, thereby forming a composite conical prism.

12. The sunlight conversion unit of claim 11, wherein all polyhedrons are the same.

13. The sunlight conversion unit of claim 11, comprising the double cone prism, wherein another prism is a mirror copy of the cone prism relative to a plane containing the first triangular faces.

14. The sunlight conversion unit of claim 8, wherein an area of said working surface of the ring is larger for shorter wavelengths of the solar spectrum.

15. The sunlight conversion unit of claim 8, wherein some or all solar cells further comprise a layer of photonic crystal for enhancing light trapping properties.

16. A solar cell system, comprising:
(i) a sunlight concentrator, collecting sunlight and converting the collected sunlight into concentrated sunlight of higher intensity;
(ii) a dispersion element receiving the concentrated sunlight and spreading the concentrated sunlight into spectral components, a range of spectral components defining a spectral band;
(iii) an array of solar cells, comprising:
a plurality of solar cells made of a photovoltaic material, each solar cell having a shape of a ring, each ring having a working surface area receiving a corresponding spectral band from the dispersion element;
the shape of each ring being formed as a complement of inner space relative to an outer space, the inner space being enclosed by the outer space;
the plurality of the solar cells being spatially arranged to form a sequence of solar cells, wherein a succeeding solar cell is enclosed within a preceding solar cell in the sequence; and
the photovoltaic material of each solar cell being optimized for converting the corresponding spectral band;
wherein a shape of the working surface of a ring substantially corresponds to a shape of an area on the working surface illuminated by the corresponding spectral band.

17. The solar cell system of claim 16, wherein the sunlight concentrator comprises one of the following:
two confocal reflectors;
two non-confocal reflectors and adjustable refractive element transforming a non-parallel beam into a substantially parallel beam.

18. The solar cell system of claim of claim 16, wherein the dispersion element comprises a composite cone prism, comprising:
a number of optical elements in a form of polyhedra made of optically transparent material;
each polyhedron having a first triangular face, and a second triangular face, one rectangular lateral face having two lateral edges, and two trapezoidal lateral faces of equal size having a common lateral edge whose length is shorter than a length of said two lateral edges, the first triangular face being perpendicular to the lateral faces;
the trapezoidal lateral faces of all polyhedra being the same;
the first and second triangular faces being polished; and
the number of polyhedra and angles of triangular faces are chosen so that to ensure the polyhedra are assembled together so that trapezoidal lateral faces of any two neighboring polyhedra coincide, thereby forming a composite conical prism.

19. The solar cell system of claim 16, wherein an area of said working surface of the ring is larger for shorter wavelengths of the solar spectrum.

20. The solar cell system of claim 16, wherein some or all solar cells further comprise a layer of photonic crystal for enhancing light trapping properties.
